(19) United States
(12) Patent Application Publication
(10) Pub. No.: US 2017/0349992 A1
(43) Pub. Date: Dec. 7, 2017

(54) PROCESSING COMPONENT HAVING IMPROVED PLASMA ETCHING RESISTANCE, AND TREATMENT METHOD FOR REINFORCING PLASMA ETCHING RESISTANCE OF PROCESSING COMPONENT

(71) Applicants: Ok Ryul KIM, Yongin-si (KR); Ok Min KIM, Yongin-si (KR); FEMVIX CORP., Yongin-si (KR)

(72) Inventors: Ok Ryul KIM, Yongin-si (KR); Ok Min KIM, Yongin-si (KR)

(73) Assignees: FEMVIX CORP, Yongin-si (KR); Ok Ryul KIM, Yongin-si (KR); Ok Min KIM, Yongin-si (KR)

(21) Appl. No.: 15/524,045

(22) PCT Filed: Nov. 4, 2015
(86) PCT No.: PCT/KR2015/011755

§ 371 Date: May 3, 2017

(30) Foreign Application Priority Data
Nov. 7, 2014 (KR) 10-2014-0154200

(51) Int. Cl. C23C 4/11; C23C 4/134; C23C 4/18; H01J 37/32; C23C 4/02; H01L 21/67

(52) U.S. Cl. CPC C23C 4/11; H01J 37/32495; C23C 4/02; C23C 4/134; C23C 4/18; H01J 2237/334; H01L 21/67069

(57) ABSTRACT

Provided is a processing component of equipment for manufacturing a semiconductor or a display. A ceramic coated film is formed on a surface of a body of the processing component, in a state in which some or the entirety of valleys and peaks are removed, such that a surface roughness Rz, which is expressed as an absolute value (P1+P2+P3+P4+P5)/5−(V1+V2+V3+V4+V5)/5 corresponding to a difference between an average of distances between the deepest five valleys V1, V2, V3, V4 and V5 in a section in which the surface roughness is measured and an arbitrary datum line that is parallel to a center line at which an area of peaks and an area of valleys are equal to each other in the section in which the surface roughness is measured and an average of distances between the highest five peaks P1, P2, P3, P4 and P5 in the section in which the surface roughness is measured and the arbitrary datum line, is lower than 5.0 μm.

### TECHNICAL FIELD

The present invention is conceived to solve a problem that a processing component of equipment for manufacturing a semiconductor or a display is exposed to plasma to be etched, and relates to a method for improving plasma etching resistance by removing a valley and a peak from a surface (a surface of a body of a processing component and a surface of a coating film) before and after the processing component is coated with ceramic powder.

### BACKGROUND ART

The present invention relates to a method for improving plasma etching resistance of a processing component of equipment for manufacturing a semiconductor or a display, and a processing component formed by the method and having improved plasma etching resistance. Some or the entirety of valleys and peaks are removed from a surface of the processing component before ceramic powder having excellent plasma etching resistance is sprayed and coated and a surface of a coating film after the ceramic powder is sprayed and coated, plasma etching developed in the valleys and the peaks of a coating film is adjusted, and thus the processing component is protected from a plasma environment, so that manufacturing productivity and yield rates for the semiconductor and the display may be improved.

The conventional technology for improving plasma etching resistance of a processing component of equipment for manufacturing a semiconductor or a display will be described below.

Korean Patent No. 10-0607790 entitled “Processing chamber and component having textured inner surface and method for manufacturing same” and U.S. Pat. No. 6,933,025 entitled “Chamber having components with textured surfaces and method of manufacture” correspond to a technology in which a ceramic coated part that is plasma-sprayed to a rough surface of a dome-type container wall for a plasma chamber, which has an average roughness of 150 to 450 micro-inch, is applied to a rough surface of a dielectric material, and the plasma-sprayed ceramic coated part is textured to have an average skewness having a negative value, so that a surface of a component has good particle adhesiveness. However, because there is a problem in that etching caused by plasma is developed in the valleys and the peaks on the surface of the plasma-sprayed coated part at a high speed, there is a problem in that particles may occur.

A method for low temperature aerosol deposition of a plasma resistive layer on a semiconductor chamber component/element is disclosed in Korean Patent No. 10-0938474 entitled “Low temperature aerosol deposition of plasma protection layer” and U.S. Pat. No. 7,479,464 entitled “Low temperature aerosol deposition of plasma resistive layer”. This technology corresponds to a technology of preventing a plasma resistive layer formed of yttrium oxide from being cracked or recessed during a plasma process, by forming a coupling layer between a substrate surface and the plasma resistive layer. However, this technology has a disadvantage in that, because the coupling layer is formed to resolve lack of the coupling force between the substrate and the coating layer by the low temperature aerosol deposition, valleys and peaks on the surface of the coating layer are maintained to have the same form as that of valleys and peaks of the coupling layer, so that plasma etching is developed in the valleys and the peaks on the surface of the coating layer.

A technology in which a plasma resistant yttria (Y₂O₃) coated film is formed on a surface of a processing component using an aerosol deposition method, and texture of an interconnected scratch is formed by polishing a surface of the coating film using a diamond pad, so that generation of particles by building up a film on a plasma-exposed surface, is disclosed in Korean Patent Application Publication No. 10-2013-0044170 entitled “Component of plasma processing chamber having textured plasma resistant coating” and U.S. Patent Application Publication No. US 2013/0102156 entitled “Components of plasma processing chambers having textured plasma resistant coatings”. However, this technology corresponds to a technology in which an yttria coated film is formed in a processing component using an aerosol deposition method and is then polished. Because the yttria coated film is formed in the processing component using the aerosol deposition method without separate processing such as the above-described coupling layer of U.S. Pat. No. 7,479,464 and the coating film is polished, the shapes of valleys and peaks on the surface of the processing component before coating are represented in a structure of the surface of the coating film as it is. Thus, there is a disadvantage in that because a large thickness of the coating film should be removed to remove the valleys and the peaks on the surface of the coating film, a large thickness of the coating film should be formed during the coating. Further, the coating film formed by coating without removing the valleys and the peaks on the surface of the processing component before the coating has degraded plasma etching resistance as described above.

A technology disclosed in U.S. Patent Application Publication No. US 2013/0273327 entitled “Ceramic coated article and process for applying ceramic coating” corresponds to a technology in which a surface of a processing component formed of alumina (Al₂O₃) is roughened through bead blasting, a ceramic coated film is formed along the rough surface using a plasma spraying method, and a surface of the coating film is smoothened by polishing the rough surface of the ceramic coated film. This technology corresponds to polishing the surface of the coating film but has a problem in that pores and cracks are distributed in the entire coating film, and thus plasma etching is developed in valleys and peaks on the surface of the coating film, which is exposed to plasma.

A technology disclosed in Korean Patent Application Publication No. 10-2014-0100030 entitled “Surface treatment method and ceramic structure using same” corresponds to a technology in which a base material is coated with ceramic using a plasma spraying method by blast processing, and a coating film is polished. However, the technology has a problem in that even when the coating film is polished after the coating, pores and cracks on a surface of the coating film are distributed in the entire coating film, and thus plasma etching is developed in valleys and peaks on the surface of the coating film, which is like U.S. Patent Application Publication No. US 2013/0273327.

(Patent Document 1) 1. Korean Patent No. 10-0607790 entitled “Processing chamber and component having textured inner surface and method for manufacturing same”

(Patent Document 2) 2. U.S. Pat. No. 6,933,025 entitled “Chamber having components with textured surfaces and method of manufacture”

(Patent Document 3) 3. Korean Patent No. 10-0938474 entitled “Low temperature aerosol deposition of plasma protection layer”

(Patent Document 4) 4. U.S. Pat. No. 7,479,464 entitled “Low temperature aerosol deposition of plasma resistive layer”

(Patent Document 5) 5. Korean Patent Application Publication No. 10-2013-0044170 entitled “Component of plasma processing chamber having textured plasma resistant coating”

(Patent Document 6) 6. U.S. Patent Application Publication No. US 2013/0102156 entitled “Components of plasma processing chambers having textured plasma resistant coatings”

(Patent Document 7) 7. U.S. Patent Application Publication No. US 2013/0273327 entitled “Ceramic coated article and process for applying ceramic coating”

(Patent Document 8) 8. Korean Patent Application Publication No. 10-2014-0100030 entitled “Surface treatment method and ceramic structure using same”

### DISCLOSURE

### Technical Problem

An object of the present invention to provide a method for improving plasma etching resistance of a processing component of equipment for manufacturing a semiconductor and a display and a processing component having improved plasma etching resistance, which is formed by the method.

### Technical Solution

To improve plasma etching resistance of a processing component of equipment for manufacturing a semiconductor or a display, a surface roughness Rz or an area ratio of a bright portion and a dark portion illustrated in a picture obtained by capturing a surface using a microscope is adjusted by removing some or the entirety of valleys and peaks from a surface of the processing component before a ceramic coated film is formed in the processing component, and a surface roughness Rz of the coating film or an area ratio of a bright portion and a dark portion illustrated in a picture obtained by capturing a surface using the microscope is adjusted by removing some or the entirety of valleys and peaks from a surface of coating film after the ceramic coated film is formed on the processed surface of the processing component, so that plasma etching resistance developed in the valleys and the peaks on the surface of the ceramic coated film may be improved. Further, when the coating film is formed so as not have pores and cracks, the plasma etching resistance may be further improved.

The present invention provides [a processing component of equipment for manufacturing a semiconductor or a display, which is exposed to plasma, the processing component having improved plasma etching resistance, in which a ceramic coated film is formed on a surface of the processing component, from which some or the entirety of valleys and peaks are removed, and some or the entirety of valleys and peaks are removed from a surface of the coating film].

Further, the present invention provides [a method for improving plasma etching resistance of a processing component for equipment for manufacturing a semiconductor or a display, which is exposed to plasma, the method including: a step (a) of preparing a processing component; a step (b) of removing some or the entirety of valleys and peaks from a surface of a body of the processing component; a step (c) of forming a ceramic coated film on the surface of the body of the coating film; and a step (d) of removing some or the entirety of valleys and peaks from a surface of the coating film].

### Advantageous Effects

A processing component having improved plasma etching resistance and a treatment method for improving plasma etching resistance of a processing component, which is provided by the present invention, have the following effects.

1) Plasma etching resistance of a processing component of equipment for manufacturing a semiconductor or a display, which is exposed to plasma, may be improved.

2) The processing component having improved plasma etching resistance is mounted to the equipment for manufacturing a semiconductor or a display, so that a lifespan of the processing component may be extended and productivity and a yield rate of a product may be improved.

3) The processing component having improved plasma etching resistance is mounted to the equipment for manufacturing a semiconductor or a display, and thus generation of particles by plasma etching is suppressed, so that a process may be sequentially maintained.

### DESCRIPTION OF THE INVENTION

The patent or application file contains at least one drawing executed in color. Copies of this patent or patent application publication with color drawing(s) will be provided by the Office upon request and payment of the necessary fee.

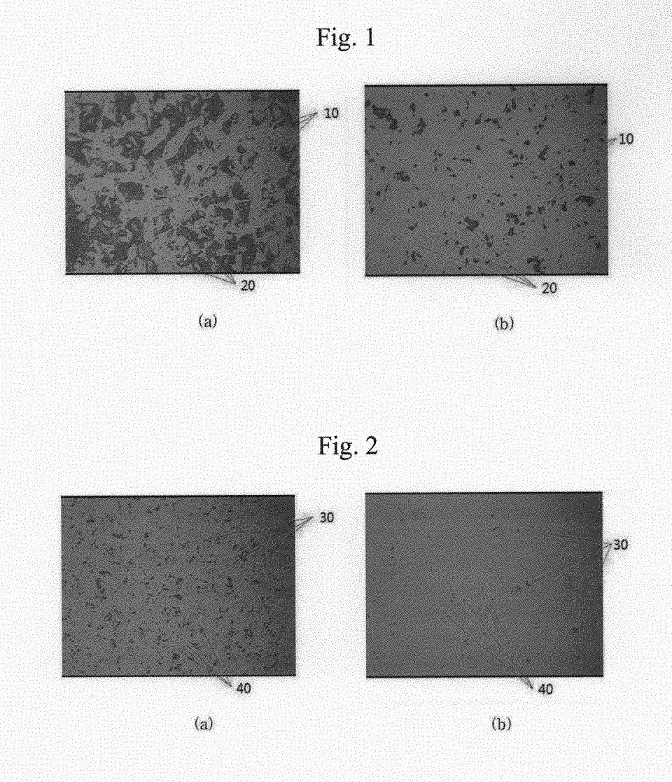

FIG. 1 are pictures obtained by capturing a surface of an alumina ceramic component by an optical microscope of 1,200 magnification, wherein (a) of FIG. 1 illustrates a state in which some of valleys and peaks are removed from a ceramic surface such that a surface roughness Rz is lower than 5.0 μm, and (b) of FIG. 1 illustrates a state in which a relative large amount of valleys and peaks are removed such that the surface roughness Rz is not more than 3.0 μm;

FIG. 2 are pictures obtained by capturing, by the optical microscope of 1,200 magnification, a surface of a coating film formed by coating the surface of the alumina ceramic component with yttria (Y₂O₃), wherein (a) of FIG. 2 illustrates a state in which valleys and peaks are removed from the surface of the coating film such that the surface roughness Rz is lower than 2.0 μm, and (b) of FIG. 2 illustrates a state in which a relative large amount of the valleys and the peaks are removed such that such that the surface roughness Rz is not more than 1.0 μm;

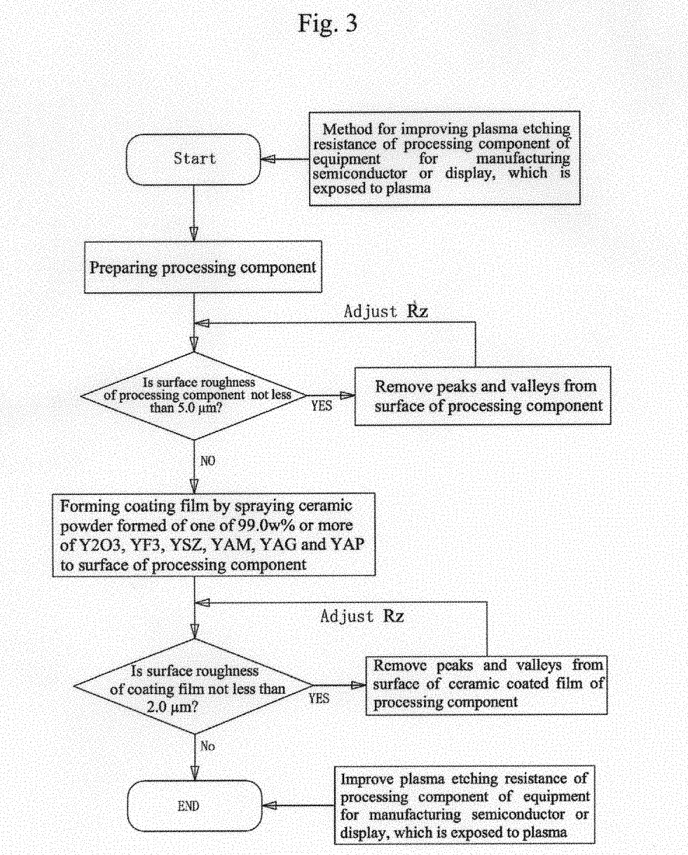

FIG. 3 is a flowchart illustrating a method for improving plasma etching resistance of a processing component of equipment for manufacturing a semiconductor or a display, which is exposed to plasma;

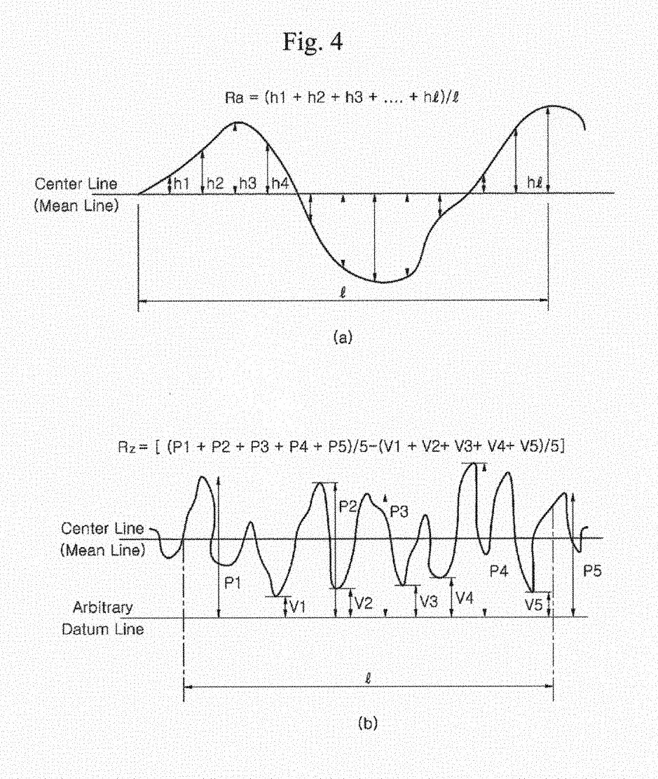

(a) of FIG. 4 is a graph for explaining the surface roughness Ra and (b) of FIG. 4 is a graph for explaining the surface roughness Rz;

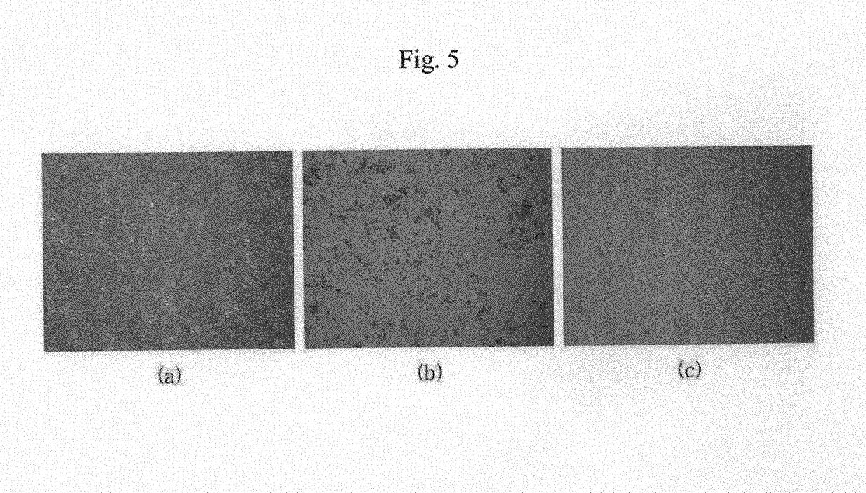

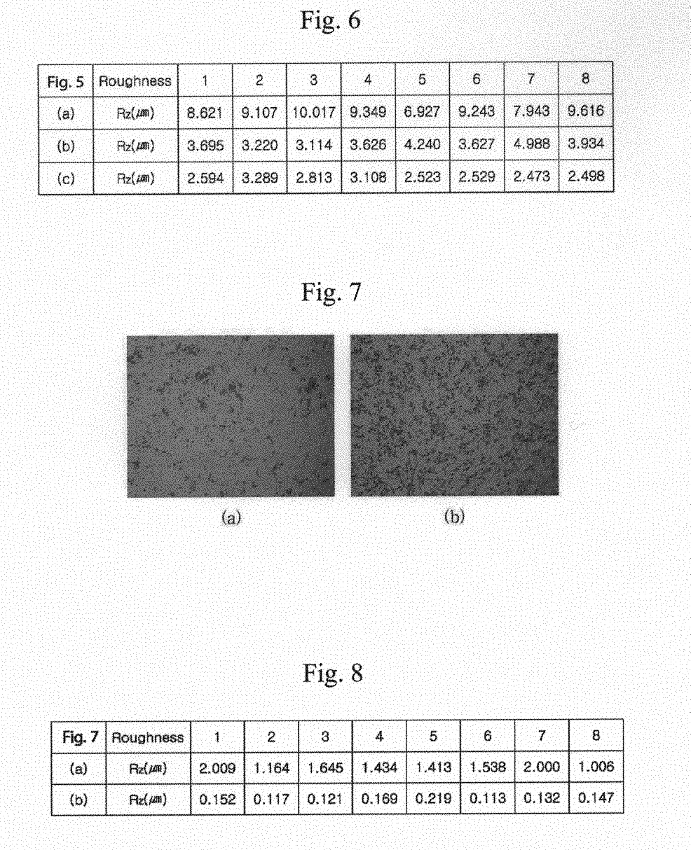

FIG. 5 are pictures captured by the optical microscope of 1,200 magnification, wherein (a) of FIG. 5 illustrates a surface of the alumina ceramic component, (b) of FIG. 5 illustrates a state in which some of the valleys and the peaks are removed from the surface of the alumina ceramic component, and (c) of FIG. 5 illustrates a surface of the yttria (Y₂O₃) coated film formed on the surface of the alumina ceramic component, from which some of the valleys and the peaks are removed;

FIG. 6 is a table representing values of the surface roughness of (a), (b) and (c) of FIG. 5;

FIG. 7 are pictures captured by the optical microscope of 1,200 magnification, wherein (a) of FIG. 7 illustrates a state in which some of the valleys and the peaks are removed from the surface of the alumina ceramic component, and (b) of FIG. 7 illustrates a state in which some of the valleys and the peaks are removed from the surface of the (Y₂O₃) coated film formed on the surface of the alumina ceramic component;

FIG. 8 is a table representing values of the surface roughness of (a) and (b) of FIG. 7;

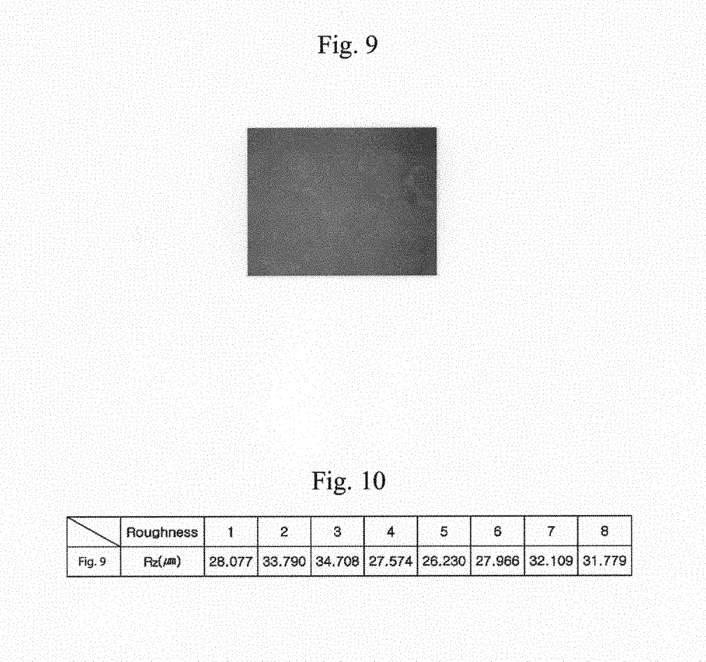

FIG. 9 is a picture obtained by capturing the surface of the Y₂O₃ coated film by the optical microscope of 1,200 magnification after the surface of the alumina ceramic component is blasted;

FIG. 10 is a table representing values of the surface roughness Rz of a thermal spray-coated film of FIG. 9;

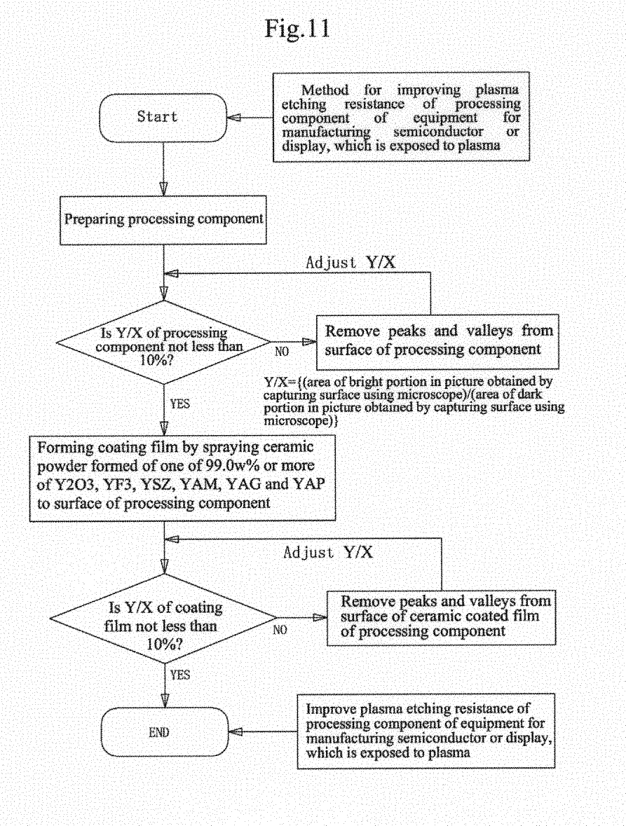

FIG. 11 is a flowchart illustrating another method for improving plasma etching resistance of a processing component of equipment for manufacturing a semiconductor or a display, which is exposed to plasma;

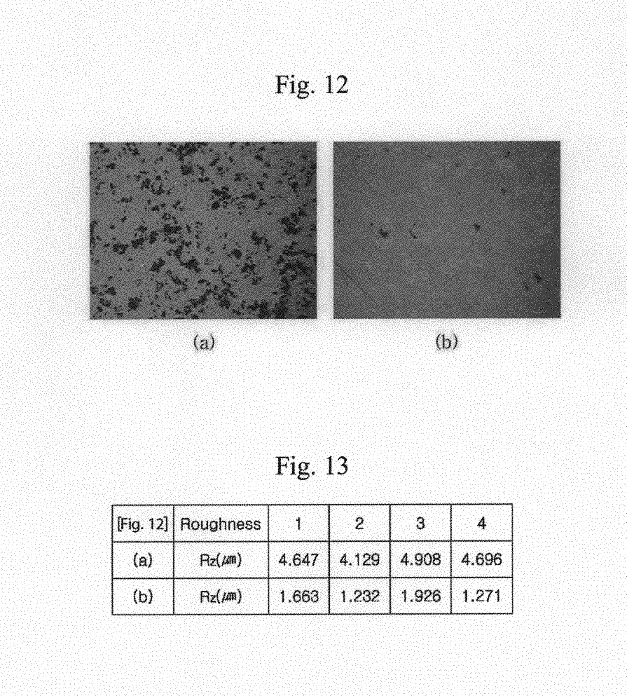

FIG. 12 are pictures captured by the optical microscope of 1,200 magnification, wherein (a) of FIG. 12 illustrates a state in which some of valleys and peaks are removed from a surface of an aluminum-nitride ceramic component, and (b) of FIG. 12 illustrates a state in which some of valleys and peaks are removed from a surface of a Y₂O₃ coated film formed on a surface of the aluminum-nitride ceramic component;

FIG. 13 is a table representing values of the surface roughness Rz of (a) and (b) of FIG. 12;

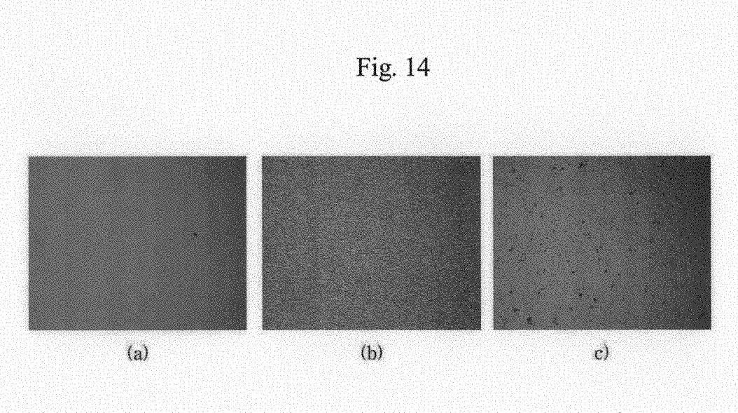

FIG. 14 are pictures captured by the optical microscope of 1,200 magnification, wherein (a) of FIG. 14 illustrates a state in which some of valleys and peaks are removed from a quartz surface, (b) of FIG. 14 illustrates a surface of a yttria (Y₂O₃) coated film formed on the quartz surface from which valleys and peaks are removed, and (c) of FIG. 14 illustrates a state in which some of the valleys and the peaks are removed from a surface of the yttria (Y₂O₃) coated film formed on the quartz surface from which valleys and peaks are removed; and

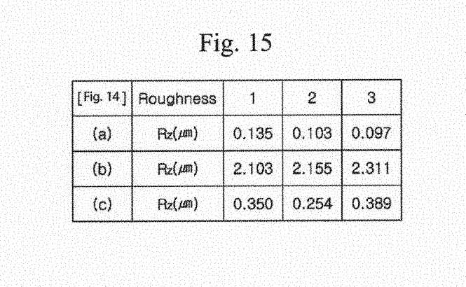

FIG. 15 is a table representing values of the surface roughness Rz of (a), (b) and (c) of FIG. 14.

### BEST MODE

The best mode for implementing embodiments of the present invention will be described below.

1. Processing Component having Improved Plasma Etching Resistance

The best mode of a processing component having improved plasma etching resistance according to the present invention is [a processing component of equipment for manufacturing a semiconductor or a display, the processing component having improved plasma etching resistance, in which a ceramic coated film is formed on a surface of a body of a processing component in a state in which some or the entirety of valleys and peaks are removed such that the surface roughness Rz, which is expressed as an absolute value (P1+P2+P3+P4+P5)/5−(V1+V2+V3+V4+V5)/5 corresponding to a difference between an average of distances between the deepest five valleys V1, V2, V3, V4 and V5 in a section in which the surface roughness is measured and an arbitrary datum line parallel to a center line at which an area of peaks and an area of valleys are equal to each other in the section in which the surface roughness is measured and an average of distances between the highest five peaks P1, P2, P3, P4 and P5 in the section in which the surface roughness is measured and the arbitrary datum line, is not more than 5.0 μm, some or the entirety of valleys or peaks existing on the surface of the coating film are removed, and the coating film is formed of any one of yttria (Y₂O₃), yttrium fluoride (YF₃), Y₂O₃ stabilized ZrO₂ (YSZ), Y₄Al₂O₉ (YAM), Y₃Al₅O₁₂ (YAG) and YAP (YA₁O₃), has no pore and crack, and has surface roughness that is lower than 2.0 μm].

2. Method for Improving Plasma Etching Resistance of Processing Component

The best mode of a method for improving plasma etching resistance of a processing component according to the present invention is [a method for improving plasma etching resistance of a processing component of equipment for manufacturing a semiconductor or a display, which is exposed to plasma, the method including: a step (a) of preparing the processing component; a step (b) of removing some or the entirety of valleys and peaks from a surface of a body of the processing component such that the surface roughness Rz, which is expressed as an absolute value (P1+P2+P3+P4+P5)/5−(V1+V2+V3+V4+V5)/5 corresponding to a difference between an average of distances between the deepest five valleys V1, V2, V3, V4 and V5 in a section in which the surface roughness is measured and an arbitrary datum line parallel to a center line at which an area of peaks and an area of valleys are equal to each other in the section in which the surface roughness is measured and an average of distances between the highest five peaks P1, P2, P3, P4 and P5 in the section in which the surface roughness is measured and the arbitrary datum line, is not more than 5.0 μm; a step (c) of forming a ceramic coated film on the surface of the body of the processing component; and a step (d) of removing some or the entirety of valleys and peaks from a surface of the coating film, wherein in step (c), the coating film is formed by spraying ceramic powder formed of any one or two or more of yttria (Y₂O₃), yttrium fluoride (YF₃), Y₂O₃ stabilized ZrO₂ (YSZ), Y₄Al₂O₉ (YAM), Y₃Al₅O₁₂ (YAG) and YAP (YAlO₃), and in step (d), the surface roughness Rz of the coating film is lower than 2.0 μm].

### [Mode]

Hereinafter, a processing component having improved plasma etching resistance and a method for improving plasma etching resistance of the processing component according to the present invention will be described in detail with reference to the accompanying drawings.

1. Processing Component having Improved Plasma Etching Resistance

The present invention provides [a processing component of equipment for manufacturing a semiconductor or a display, which is exposed to plasma, the processing component having improved plasma etching resistance, in which a ceramic coated film is formed on a surface of a body of the processing component in a state in which some or the entirety of valleys and peaks are removed such that the surface roughness Rz, which is expressed as an absolute value (P1+P2+P3+P4+P5)/5−(V1+V2+V3+V4+V5)/5 corresponding to a difference between an average of distances between the deepest five valleys V1, V2, V3, V4 and V5 in a section in which the surface roughness is measured and an arbitrary datum line parallel to a center line at which an area of peaks and an area of valleys are equal to each other in the section in which the surface roughness is measured and an average of distances between the highest five peaks P1, P2, P3, P4 and P5 in the section in which the surface roughness is measured and the arbitrary datum line, is not more than 5.0 μm, and some or the entirety of valleys and peaks existing on a surface of the coating film are removed].

The processing component according to the present invention is formed of any one of ceramic, quartz, metal and polymer. A coating film is formed by spraying ceramic powder to a surface of the processing component. Any one or two or more of yttria (Y₂O₃), yttrium fluoride (YF₃), YSZ (Y₂O₃ stabilized ZrO₂), YAM (Y₄Al₂O₉), YAG (Y₃Al₅O₁₂) and YAP (YAlO₃), which have excellent plasma etching resistance, may be applied to the ceramic powder forming the coating film. It is preferred that a material having concentration of 99% is applied to the ceramic powder.

The coating film may be formed so as not to include pores and cracks by spraying the ceramic powder at a temperature of 0-60 □ and in a vacuum condition, as illustrated in (b) of FIG. 2, (b) of FIG. 7, (b) of FIG. 12, and (b) and (c) of FIG. 14.

The valleys and the peaks existing on the surface of the body of the processing component before the ceramic powder is sprayed to and coated in the surface of the body of the processing component act as cause of plasma etching even after the ceramic coated film is formed. Accordingly, some or the entirety of the valleys and the peaks on the surface of the body of the processing component are removed, so that a plasma etching rate may be reduced. Further, the valleys and the peaks existing on the surface of the coating film formed by spraying and coating the ceramic powder to and in the surface of the body of the processing component also act as cause of plasma etching. Accordingly, some or the entirety of the valleys and the peaks are removed from the surface of the coating film, so that the plasma etching rate may be further reduced. The thickness of the coating film after the valleys and the peaks are removed may be 2.0-15 μm. An initial thickness of the coating film after coating is formed to be 3.0-20 μm such that the surface roughness Rz of the coating film is formed to be lower than 2.0 μm after the valleys and the peaks are removed, and the thickness of the coating film may be maintained to be 2.0-15 μm by removing the valleys and the peaks of the coating film, so that plasma etching resistance may be improved.

A degree to which the valleys and the peaks are removed from the surface of the body of the processing component (before the coating film is formed) and the surface of the coating film may be quantified by calculating the surface roughness Rz or analyzing the pictures captured by the optical microscope.

In case of the surface roughness Rz, when the surface roughness Rz of the surface of the body of the processing component is lower than 5.0 μm, the plasma etching resistance may be improved. For example, the ceramic processing component is generally formed through sintering, and the surface roughness Rz of the sintered product is formed to be not less than 5.0 μm. Further, when the valleys and the peaks are removed from the surface of the sintered product, the surface roughness Rz of the sintered product is reduced to be lower than 5.0 μm, so that the plasma etching developed in the valleys and the peaks may be reduced. The above mechanism may be also represented in quartz. The surface of the processing component formed of metal such as aluminum is generally formed in a constant pattern or in an irregular pattern, the surface roughness Rz is formed to be not less than 5.0 μm, and when the valleys and the peaks (patterns) are removed from the surface of the processing component, the surface roughness Rz of the processing component is reduced to be lower than 5.0 μm.

Further, when the surface roughness Rz of the surface of the ceramic coated film formed on the surface of the body of the processing component is lower than 2.0 μm, plasma etching resistance is improved. For example, as illustrated in (c) of FIG. 5, after Y₂O₃ ceramic powder is sprayed and coated, the surface roughness Rz of the Y₂O₃ coated film is distributed in a range of 2.498-3.289 μm that is not less than 2.0 μm. To improve plasma etching resistance of the surface of the coating film, after the Y₂O₃ coated film is formed, when the surface roughness Rz of the coating film is formed to be lower than 2.0 μm as illustrated in (b) of FIG. 7, the plasma etching developed in the valleys and the peaks on the surface of the coating film may be reduced.

Thus, when the valleys and the peaks are removed from the surface of the processing component or the surface of the coating film through means such as cutting, grinding, brushing, polishing, lapping and chemical polishing, whether a surface treatment operation is performed is determined under the surface roughness Rz (the surface roughness of the surface of the body of the processing component before coating) of 5.0 μm and the surface roughness Rz (the surface roughness of the coating film) of 2.0 μm.

Meanwhile, as illustrated in FIG. 4, in a representative method for expressing the surface roughness of a processing component, the surface roughness Ra (=h1+h2+ . . . +h1)/1 is an arithmetic mean of distances h between a central line at which an area of peaks and an area of valleys are identical to each other and the peaks and the valleys, in a predetermined length 1 in which a surface roughness measurement probe performs measurement, or the surface roughness Rz (={[P1+P2+P3−P4+P5]/5}−{[V1+V2+V3+V4+V5]/5}) is a distance between an average of five lengths between an arbitrary datum line and the peaks along the predetermined length 1 and an average of five lengths between the arbitrary datum line and the valleys. As identified in the expression equation of the surface roughness, a plasma etching property of the plasma etching concentrated and developed in the valleys and the peaks on the surface of the processing component may be better evaluated when the evaluation is performed using not the Ra (see (a) of FIG. 4) but the surface roughness Rz (see (b) of FIG. 4). This is because the surface roughness Rz is a value obtained by more sensitively measuring a degree to which the surface of the processing component is recessed. Here, the surface roughness Rz is larger than the surface roughness Ra.

Meanwhile, a reference for analyzing a picture captured by the optical microscope will be described below. When the picture obtained by photographing the surface of the coating film using the optical microscope is divided into a bright portion and a dark portion depending on relative brightness, if an area of the bright portion is not less than 10% of an area of the dark portion, the plasma etch property may be improved. Likewise, when the picture obtained by photographing the surface of the body of the processing component using the optical microscope is divided into a bright portion and a dark portion depending on the relative brightness, if an area of the bright area is not less than 10% of an area of the dark area, the plasma etching property may be improved.

As illustrated in FIGS. 1 and 2, bright portions 20 and 40 in the picture captured by the optical microscope are brightly-displayed portions as valleys and peaks are flattened using a combined removal method for valleys and peaks and light is reflected. Further, the fact that the brightly-displayed portions are wide means that the surface of the body of the processing component or the surface of the ceramic coated film of the processing component is flattened. In this case, the surface roughness Rz is lower than 5.0 μm (the surface roughness Rz is small), and the plasma etch property is improved.

Hereinafter, the method for improving plasma etching resistance of a processing component will be described in detail.

### 2. Method for Improving Plasma Etching Resistance of Processing Component

The present invention provides, together, [a step of removing some or the entirety of valleys and peaks from a surface of a body of a processing component such that the surface roughness Rz that is expressed as an absolute value (P1+P2+P3+P4+P5)/5−(V1+V2+V3+V4+V5)/5 corresponding to a difference between an average of distances between the deepest five valleys V1, V2, V3, V4 and V5 and an arbitrary datum line that is parallel to a center line at which an area of the peaks and an area of the valleys are identical to each other in a section in which the surface roughness is measured and an average of distances between the highest peaks P1, P2, P3, P4 and P5 and the arbitrary datum line is lower than 5.0 μm].

Any one of cutting, grinding, brushing, polishing, lapping and chemical polishing or a combination of two or more thereof may be applied to the method for removing the valleys and the peaks from the surface of the body of the processing component and the surface of the coating film.

In step (c), the ceramic powder is sprayed at a temperature of 0-60 □ and in a vacuum condition so that cracks and pores are prevented from being generated on the ceramic coated film. Any one of Y₂O₃, YF₃, YSZ, Y₄Al₂O₉, Y₃Al₅O₁₂ and YAlO₃ or a combination of two or more thereof may be applied to the ceramic powder.

Whether the valleys and the peaks are removed from the surface of the body of the processing component (before the coating film is formed) and the surface of the coating film, a workload and the like may be determined through the surface roughness Rz or through analyzing the pictures captured by the optical microscope.

FIG. 3 schematically illustrates progress of steps according to the surface roughness.

In this case, an operation of removing valleys and peaks is performed such that in step (b), the surface roughness Rz of the body of the processing component is lower than 5.0 μm, and in step (d), the surface roughness Rz of the coating film is lower than 2.0 μm.

That is, in step (b), when the surface roughness Rz of the body of the processing component is identified, if the surface roughness Rz of the body of the processing component is not less than 5.0 μm, an operation of removing valleys and peaks from the surface of the body of the processing component is performed such that the surface roughness Rz becomes lower than 5.0 μm. Further, in step (d), valleys and peaks are removed from the surface of the ceramic coated film such that the surface roughness Rz of the surface of the ceramic coated film becomes lower than 2.0 μm.

In more detail, as illustrated in FIGS. 5 and 6, when the surface roughness Rz of the body of the processing component is not less than 5.0 μm (see (a) of FIG. 5), the surface roughness Rz of the processing component is adjusted to be lower than 5.0 μm by removing some of the peaks and the valleys, as illustrated in (b) of FIG. 5.

Further, when a coating film without pores and cracks is formed by spraying and coating the ceramic powder as illustrated in (c) of FIG. 5, the surface roughness Rz of the ceramic coated film becomes not less than 2.0 μm. Here, when the valleys and the peaks are removed from the surface of the coating film such that the surface roughness is lower than 2.0 μm as illustrated in (b) of FIG. 7, the plasma etching resistance becomes much larger than that of (c) of FIG. 5.

Further, a coating film illustrated in (a) of FIG. 7 has much larger plasma etching resistance than that of the coating film illustrated in (b) of FIG. 5. When the surface roughness Rz is lower than 5.0 μm as illustrated in (a) of FIG. 7, if the surface roughness Rz of a coating film is lower than 2.0 μm after the coating film is formed as illustrated in (b) of FIG. 7, the plasma etching resistance of the coating film of the processing component becomes much larger.

Further, the coating film illustrated in (a) of FIG. 7 has much larger plasma etching resistance than that of the coating film illustrated in (b) of FIG. 5. When the surface roughness Rz has a small value that is lower than 5.0 μm as illustrated in (a) of FIG. 7, if the surface roughness Rz of the coating film is lower than 2.0 μm after the coating film is formed as illustrated in (b) FIG. 7, the plasma etching resistance of the coating film of the processing component becomes much larger.

For example, as illustrated in FIG. 7, the plasma etching resistances of the surface of the body of the processing component and the coating film of the processing component, from which the valleys and the peaks of the coating film of the processing component are removed after the coating, are larger than, by 50% or more, the plasma etching resistance of a coating film on which a yttria coated film is formed in a state in which valleys and peaks are not removed from the surface of the processing component before coating by Korean Patent Application Publication No. 10-2013-0044170 entitled “Component of plasma processing chamber having textured plasma resistant coating” and U.S. Patent Application Publication No. US 2013/0102156 entitled “Components of plasma processing chambers having textured plasma resistant coating”, which are described above. That is, this means that although a processing component according to U.S. Patent Application Publication No. US 2013/0102156 may be used for 6,000 hours while being exposed to plasma, the processing component according to the present invention may be used for 12,000 hours while being exposed to plasma.

Thus, to improve the plasma etching resistance of the processing component, the valleys and the peaks should be removed from the surface of the processing component such that the surface roughness Rz of the processing component before ceramic coating has as small value as possible. Further, the surface roughness Rz of the ceramic coated film should be as small as possible by removing the valleys and the peaks from the surface of the coating film even after the ceramic coating. This is because the plasma etching resistance becomes larger as the surface roughness Rz of the processing component before the coating and the surface roughness Rz of the ceramic coated film of the processing component after the coating become smaller. However, the reason why the surface roughness Rz of the surface of the processing component and the surface roughness Rz of the coating film should not be very small is that it is impossible to make a surface treatment time for the processing component and a thickness (initial thickness) of the coating film of the processing component very large. Thus, the surface roughness Rz should be adjusted in consideration of a state of the surface of the body of the processing component before the coating and the thickness of the ceramic coated film after the coating.

Meanwhile, as illustrated in FIGS. 9 and 10, the surface roughness Rz of the surface of the coating film, which is measured after ceramic coating is implemented using a thermal spray coating scheme after the surface of the ceramic coated film is blasted, is 27.574-34.708 μm. This is contrary to a fact that the surface roughness Rz of the ceramic coated film of the processing component is measured as 0.113-0.169 μm as illustrated in FIGS. 7 and 8 according to the present invention. Thus, the processing component according to the present invention has remarkably excellent plasma etching resistance.

Meanwhile, when the surface roughness Rz of the body of the processing component is lower than 5.0 μm, step (b) may be omitted and the following steps may be sequentially performed.

FIG. 11 is flowchart illustrating progress of steps through analyzing a picture captured by an optical microscope, as a method contrary to progress of steps through identifying a surface roughness Rz.

In this case, in step (b), a picture obtained by capturing the surface of the body of the processing component using an optical microscope is divided into a bright portion and a dark portion depending on relative brightness, an area Y of the bright portion is not less than 10% of an area X of the dark portion, and in step (d), a picture obtained by capturing the surface of the coating film using the optical microscope is divided into a bright portion and a dark portion depending on relative brightness, an area of the bright portion is not less than 10% of an area of the dark portion.

In detail, as illustrated in FIG. 1, it is identified whether the area Y of the bright portion 20/the area X of the dark portion 10, that is, Y/X, is lower than 10% in the picture obtained by capturing the surface of the body of the processing component (before the coating film is formed) using the optical microscope. When Y/X is lower than 10%, the valleys and the peaks may be removed from the surface of the body of the processing component such that Y/X becomes not less than 10%. Further, as illustrated in FIG. 2, it is identified whether the area Y of the bright portion 40/the area X of the dark portion 30, that is, Y/X, is not less than 10%. The valleys and the peaks may be removed from the surface of the ceramic coated film of the processing component such that Y/X becomes not less than 10%, so that the plasma etching resistance may be improved.

Here, when Y/X of the surface of the body of the processing component is not less than 10%, step (b) may be omitted and the following steps may be performed.

According to the method of the present invention, after the surface roughness Rz is formed to be 5.0 μm by removing some of the valleys and the peaks from an aluminum-nitride surface (see (a) of FIG. 12), after the coating film is formed on the aluminum-nitride surface by spraying and coating Y₂O₃ ceramic powder, when the valleys and the peaks are removed from the coating film such that the surface roughness Rz of the coating film is 2.0 μm (see FIG. 12), the plasma etching resistance may be improved.

Further, when a coating film is formed by spraying and coating Y2O3 ceramic powder to a quartz surface (see (a) of FIG. 14) on which the surface roughness Rz is in a range of 0.097-0.135 μm, the surface roughness Rz of the coating film is in a range of 2.103-2.311 μm (see (b) of FIG. 14) which is not less than 2.0 μm. When the surface roughness Rz of the coating film is adjusted to be lower than 2.0 μm (In (c) of FIG. 14, the surface roughness Rz is 0.254-0.389 μm) by removing valleys and peaks from the surface of the coating film, the plasma etching resistance of the ceramic coated film of the processing component may be improved.

Although the present invention has been described with reference to the accompanying drawings as described above, the present invention may be modified and changed without departing from the subject matter of the present invention, and may be applied to various fields. Thus, appended claims of the present invention include modifications and changes belonging to the true range of the present invention.

### DESCRIPTION OF REFERENCE NUMERALS

10: Valley portion on alumina (Al₂O₃) ceramic surface illustrated in picture captured by optical microscope of 1,200 magnification (illustrated as dark portion in picture)

20: Portion of alumina (Al₂O₃) ceramic surface, from which peaks are removed, illustrated in picture captured by optical microscope of 1,200 magnification (illustrated as bright portion in picture)

30: Valley portion of Y₂O₃ coated film formed on alumina (Al₂O₃) ceramic surface, illustrated in picture captured by optical microscope of 1,200 magnification (illustrated as dark portion in picture)

40: Portion of Y₂O₃ coated film formed on alumina (Al₂O₃) ceramic surface, from which peaks are removed, illustrated in picture captured by optical microscope of 1,200 magnification (illustrated as bright portion in picture)

### INDUSTRIAL APPLICABILITY

The present invention relates to a method for improving plasma etching resistance through removing valleys and peaks from a surface (surface of body of processing component and surface of coating film) before or after ceramic powder is coated to a processing component and a processing component having improved plasma etching resistance, which is manufactured thereby, so that a problem that a processing component of equipment for manufacturing a semiconductor or a display is etched while being exposed to plasma.

1. A processing component of equipment for manufacturing a semiconductor or a display, which is exposed to plasma, the processing component having improved plasma etching resistance, wherein a ceramic coated film is formed on a surface of a body of the processing component, in a state in which some or the entirety of valleys and peaks are removed, such that a surface roughness Rz, which is expressed as an absolute value (P1+P2+P3+P4+P5)/5−(V1+V2+V3+V4+V5)/5 corresponding to a difference between an average of distances between the deepest five valleys V1, V2, V3, V4 and V5 in a section in which the surface roughness is measured and an arbitrary datum line that is parallel to a center line at which an area of peaks and an area of valleys are equal to each other in the section in which the surface roughness is measured and an average of distances between the highest five peaks P1, P2, P3, P4 and P5 in the section in which the surface roughness is measured and the arbitrary datum line, is lower than 5.0 82 m.

2. The processing component of claim 1, wherein the coating film is formed of one or more of yttria (Y₂O₃), yttrium fluoride (YF₃), Y₂O₃ stabilized ZrO₂ (YSZ), YAM (Y₄Al₂O₉), YAG (Y₃Al₅O₁₂) and YAP (YAlO₃).

3. The processing component of claim 1, wherein the coating film does not have pores and cracks.

4. The processing component of claim 1, wherein a surface roughness of the coating film is lower than 2.0 μm.

5. The processing component of claim 1, wherein when a picture obtained by capturing a surface of the coating film using an optical microscope is divided into a bright portion and a dark portion depending on relative brightness, an area of the bright portion is not less than 10% of an area of the dark portion.

6. The processing component of claim 5, wherein when a picture obtained by capturing a surface of the body using the optical microscope is divided into a bright portion and a dark portion, an area of the bright portion is not less than 10% of an area of the dark portion.

7. The processing component of claim 1, wherein the processing component is formed of one or more of ceramic, quartz, metal and polymer.

8. A method for improving plasma etching resistance of a processing component of equipment for manufacturing a semiconductor or a display, which is exposed to plasma, the method comprising:
a step (a) of preparing a processing component;
a step (b) of removing some or the entire of valleys and peaks from a surface of a body of the processing component such that a surface roughness Rz, which is expressed as an absolute value (P1+P2+P3+P4+P5)/5−(V1+V2+V3+V4+V5)/5 corresponding to a difference between an average of distances between the deepest five valleys V1, V2, V3, V4 and V5 in a section in which the surface roughness is measured and an arbitrary datum line parallel to a center line at which an area of peaks and an area of valleys are equal to each other in the section in which the surface roughness is measured and an average of distances between the highest five peaks P1, P2, P3, P4 and P5 in the section in which the surface roughness is measured and the arbitrary datum line, is lower than 5.0 μm;
a step (c) of forming a ceramic coated film on the surface of the body of the processing component; and
a step (d) of removing some or the entirety of valleys and peaks from a surface of the coating film.

9. The method of claim 8, wherein in step (d), a surface roughness of the coating film is lower than 2.0 μm.

10. The method of claim 8, wherein in step (b), a picture obtained by capturing the surface of the body of the processing component using an optical microscope is divided into a bright portion and a dark portion depending on relative brightness, and an area of the bright portion becomes not less than 10% of an area of the dark portion, and
wherein in step (d), a picture obtained by capturing the surface of the coating film using the optical microscope is divided into a bright portion and a dark portion depending on relative brightness, and an area of the bright portion becomes not less than 10% of an area of the dark portion.

11. The method of claim 8, wherein one or more of cutting, grinding, brushing, polishing, lapping and chemical polishing are applied to a scheme of removing the valleys and the peaks from the surface of the body of the processing component and the surface of the coating film.

12. The method of claim 8, wherein in step (c), the coating film is formed by spraying ceramic powder formed of any one or two or more of yttria (Y₂O₃), yttrium fluoride (YF₃), Y₂O₃ stabilized ZrO₂ (YSZ), YAM (Y₄Al₂O₉), YAG (Y₃Al₅O₁₂) and YAP (YAlO₃).
